(19) United States
(12) Patent Application Publication
(10) Pub. No.: US 2002/0091976 A1
(43) Pub. Date: Jul. 11, 2002

(54) Reverse parity coding

(76) Inventor: Whay Sing Lee, Newark, CA (US)

Correspondence Address: Marc. R Ascolese, SKJERVEN MORRILL MacPHERSON LLP, 25 Metro Drive, Suite 700, San Jose, CA, 95110-1349, US

(21) Appl. No.: 09/757,160

(22) Filed: Jan. 9, 2001

(51) Int. Cl. G01R 31/28; H04L 1/14; G06F 11/00; H03M 13/00

(52) U.S. Cl. 714/712; 714/750; 714/800

(57) ABSTRACT

The present invention is directed to an apparatus and method to detect errors in bits of a binary coded data word transmitted from a sender device to a receiver device by having the sender device determine and store the parity of the data word, transmitting the data word to the receiver device, the receiver device determines the parity of the received data word, transmits the parity of the received data word to the sender device and the sender device compares the stored parity against the received parity. Variations include a pipelining of sending and receiving data words, using parity store registers to allow continuous cycles of transmission and only retransmitting if an error is detected. Another variation includes multiple devices as senders and receivers forming a virtual network in which sender and receiver devices can transmit data words and send back errors along the network.

### BACKGROUND OF THE INVENTION

1. Field of the Invention

This invention relates to an error detection scheme in a signaling system.

2. Description of the Related Art

Parity error detection schemes for identifying transmission errors are common in signaling systems, data paths, and memory chips. Parity error detection schemes are also used in digital information systems, computers, and various electronic machines.

A data word typically, but not necessarily is a byte length or 8-bit word. In a parity error detection scheme, a separate parity bit is provided. The parity bit is determined by the values of the other 8 bits. Using a parity error detection scheme allows the detection of single bit errors in data words sent by a sender device to a receiver device.

Two common variations of the parity error detection scheme currently are used. There is the odd parity error detection scheme (odd parity) and the even parity error detection scheme (even parity). In odd parity, the parity bit is set to a “1” if there are an even number of 1's in the other seven bits of the data word. If the number of 1's in the seven bits of the data word is odd, then the parity bit is set to “0.” Under odd parity, this assures that a sent word will always have an odd number of 1's. If the receiver does not “count” an odd number of 1's then the received data word has been corrupted. An odd number of 1's shows a “correct” data word that is received. In even parity, and even number of 1's is sent and “correct” data words will have an even number of 1's.

Parity error detection schemes are vulnerable when an even number of bits is flipped (changed) in the transmission. In either odd parity or even parity, when an even number of bits are flipped during transmission a “correct” data word is received by the receiver. The received data word appears to the receiver to be correct because the number of received bits of each type is consistent with the received parity bit. The receiver is fooled that a data word is correct because the parity is consistent.

Now referring to FIG. 1, typically a separate parity pin or wire 110 is used to transmit the parity bit 112. The parity pin or wire 110 is in addition to the data path 105 used to transmit the data word 107. This is common practice in communication between integrated circuit (IC) chips.

The receiver 20 is able to detect when a corrupted data word is received, however, the sender 10 is unable to detect if a corrupted data word was received by the receiver 20. If informed of the corrupted data word (parity error), the sender 10 can retransmit the data word 107 to the receiver 20. A higher level protocol that informs the sender 10 of the parity can be incorporated, but a relatively long time is required to inform the sender 10 and then have the sender 10 retransmit the data word 107 and the parity bit 112.

Now referring to FIG. 2, a solution is to have the receiver 20 transmit, on a separate parity pin and line 115, to the sender 10, information that a parity error 117 has been detected. The sender 10 then is able to retransmit the data word 105 and the parity bit 112.

This solution, however, can be cost prohibitive in some situations, in particular when pin constraints exist on a pin limited IC chip. In a network using a switch IC chip that connects to many other IC chips, an “error” pin and line 115 must be added for the data path between each pair of chips, resulting in many additional pins on each chip. Furthermore, this solution is vulnerable to fault conditions, for example where the error line 115 repeatedly assets a signal indicating that the received data word is non-corrupted, i.e. is stuck at “OK.” These faults are typical when there is a short-circuit to ground, and are common in very large scale integrated (VLSI) chips. When such faults exist, the sender 10 is prevented from being informed of parity errors.

Fault conditions where the error line is stuck at “OK” can be from a manufacturing defect such as when a piece of metal is dropped on the circuit. Also as time goes by the circuit and the error line may be degraded, in particular attributed to the effect known as electro-migration, to the point that the line becomes stuck at “OK.”

Accordingly it is desirable to have parity-based error detection schemes that reduce the amount of time required to correct an error condition and/or also reduce the chances of providing erroneous error information. It is also desirable to have error detection schemes that minimize the number of transmit and receive lines used by devices, especially in applications where there is limited or constrained space to place such lines.

### SUMMARY OF THE INVENTION

In devices exchanging data words such as interconnected disks or memory devices, limited connections lines and pins exist therefore a parity scheme is provided that eliminates the need for a separate parity pin and line. Reverse parity error detection scheme (RPEDS) is a solution capable of informing the sender about a parity error, without using an parity pin and line. RPEDS can use either unused code space in the data word or a special handshake sequence, to inform the receiver of a detected parity error.

In one embodiment a device computes a parity, saves the parity and transmits the data word. Another device receives the data word and computes parity and transmits this derived parity back to the first device. An error exists if the original sent parity does not match the second parity. The first device then can retransmit the data word.

Pipelined reverse parity error detection scheme (PRPEDS) is an embodiment of RPEDS that improves performance in a system by incorporating register storage devices at the sender to temporarily store “reverse parity” data words and to inform the originating sender of a corrupted data word along the transmission.

Cascaded reverse parity error detection scheme (CRPEDS) is an embodiment of RPEDS that involves tearing down an entire communication path that extends over many chips/nodes, by relaying an error condition, or the rejection of a message by the final receiver back to the first sender.

### BRIEF DESCRIPTION OF THE DRAWINGS

The present invention can be better understood, and it's numerous objects, features and advantages made apparent to those skilled in the art by referencing the accompanying drawings. The use of the same reference number throughout the figures designates a like or similar element.

FIG. 1 is a block diagram of common parity transmission.

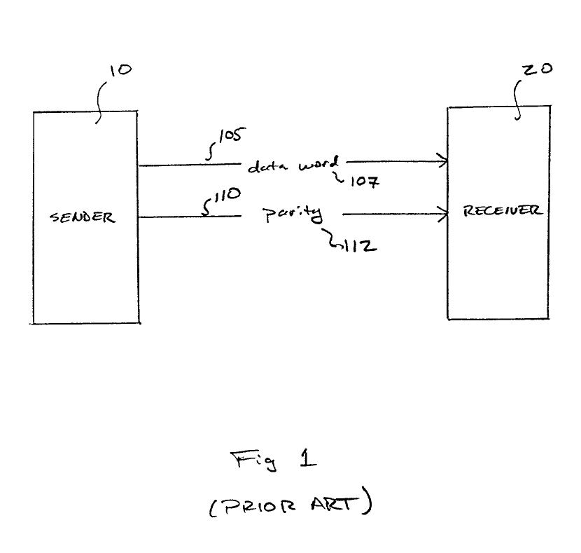

FIG. 2 is a block diagram of common parity transmission with an error line informing a sender that a corrupt data word had been sent.

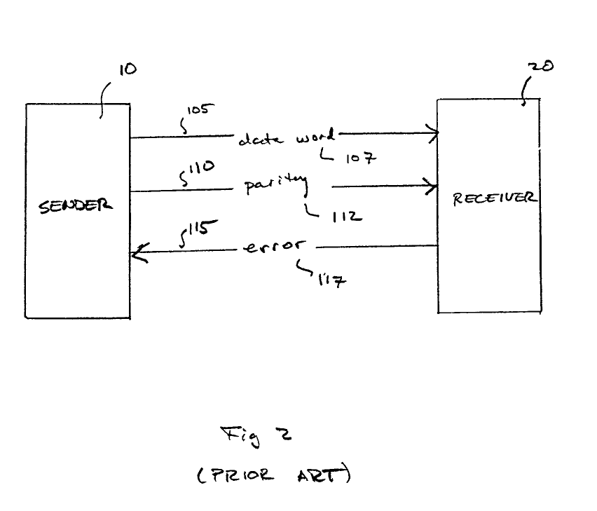

FIG. 3 is a block diagram of a reverse parity error detection scheme.

FIG. 4 is a block diagram of a reverse parity error detection scheme that includes a “data word available” pin or line and a “data word consumed” pin or line.

FIG. 5 is a block diagram of a pipeline reverse parity error detection scheme

FIG. 6 is a block diagram of a cluster of IC chips interconnected with one another, the cluster using a cascaded reverse parity error detection scheme.

While the invention is susceptible to various modifications and alternative forms, specific embodiments thereof are shown by way of example in the drawings and will herein be described in detail, it should be understood, however, that the drawings and detailed description thereto are not intended to limit the invention to the particular form disclosed but on the contrary, the intention is to cover all modifications, equivalents, and alternatives falling within the spirit and scope of the present invention as defined by the appended claims.

### DETAILED DESCRIPTION

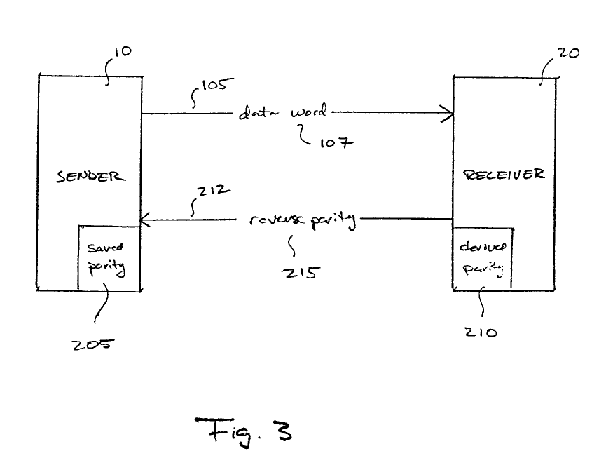

Now referring to FIG. 3, illustrated is a block diagram of a reverse parity error detection scheme (RPEDS). In RPEDS the parity bit is transmitted in the opposite, instead of the same, direction as the data word.

The sender 10 computes and remembers the parity, be it an odd number or an even number of 1's, for the data word 107 it transmits along line 105. This computed parity is called the “saved parity” 205. A single bit can be used to represent parity. For example a “1” can represent odd parity while “0” can represent even parity. The receiver 20 also computes the parity for the received data word 107. This is the derived parity 210. The derived parity 210 is sent back to the sender 10. The parity bit as perceived by the sender is the reverse parity 215 that is sent along a separate line 212.

If the reverse parity 215 does not match the saved parity 205 then it can be deduced that some error occurred. Two scenarios explain the transmission. One scenario is that the derived parity 210 is wrong, indicating that the data word 107 was received corrupted. In this case, the sender 10 correctly recognizes the corruption, and can retransmit the data word 107. Another scenario is that the data word 107 was received properly, but the reverse parity pin or line 212 was flipped. The sender 10 recognizes a “corruption” albeit a false “corruption” and retransmits the data word 107. The sender 10 unnecessarily instructs the receiver 20 to discard the previous data word 107 and wait for retransmission. This is a conservative and harmless measure, since the receiver 20 receives the same data word 107.

If the reverse parity 215 matches the saved parity 205 two scenarios explain the transmission. In one scenario, the derived parity 210 is correct, and the reverse parity pin or line 212 correctly transmitted the reverse parity 215 to the sender 10. In this scenario a successful transmission occurs. In the other scenario, the derived parity 210 is wrong, indicating that the data word 107 was received corrupted, however, in addition the reverse parity pin or line 215 is flipped. In this scenario an undetected error is transmitted. This scenario, however, requires a double error condition, both the derived parity 210 must be wrong and the reverse parity pin or line 212 must be flipped. Compared to the conventional parity error detection scheme, RPEDS performs no worse. In any of the aforementioned schemes, only single error detection is possible.

In RPEDS a separate parity signal pin or line, and an “error” pin/wire are avoided and a reverse parity pin or line 212 is used. Overall, one pin or line is eliminated with RPEDS.

In RPEDS because the receiver 10 does not receive a separate parity signal, the receiver 10 does not know per se when it has received a corrupted data word. The sender must convey that a corrupted word was transmitted when the sender sees a mismatched saved parity 205 and a reverse parity 215 pair.

The coding space is defined as the corresponding information that each unique data word represents. In a scenario where the entire coding space is not fully utilized the sender 10 and the receiver 20 use one of the unused codes as a “flag.” One example of a situation when the entire coding space is not used is when the transmitted data words 107 represent Institute of Electrical and Electronics Engineers (IEEE) formatted floating point numbers. In this specific case, certain combinations of the bits in the data word are unused. In other words, in the IEEE format certain bit word combinations do not represent any legitimate floating point numbers. These unrecognized combinations are called “Not-A-Number” (NaN). The sender 10 and receiver 20 can be designed so that a pre-arrangement or agreement can take place between the sender 10 and the receiver 20 for one of the NaN's to be used as a flag to represent a detected parity error. The sender 10 sends the selected NaN (flag) to the receiver 20 informing the receiver 20 of the detected parity error. When advised of the parity error the receiver 20 discards the preceding data word 107 and waits for retransmission.

A special handshaking pattern can be implemented if the coding space is fully occupied. An example when the coding space is fully occupied is when the data word represents an integer value. All the combinations of bits of a data word represent a valid reserved integer value and cannot be used to serve as a parity error flag.

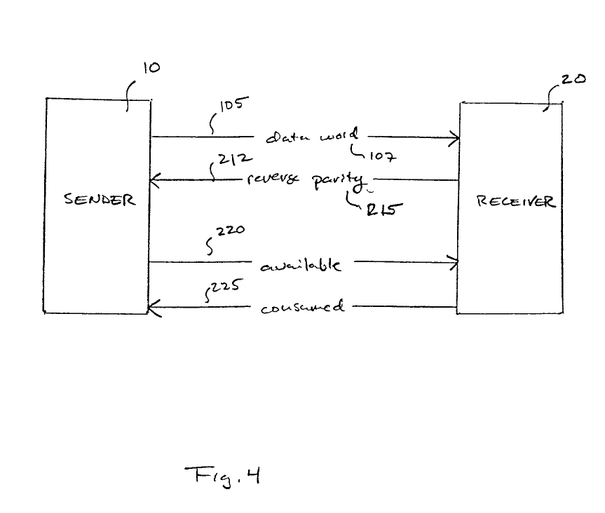

Now referring to FIG. 4, illustrated is a block diagram of an RPEDS scheme that includes a data word available pin or line and a data word consumed pin or line. Many signaling systems implement some form of flow control signal pair, such as a data word available pin or line 220 and a data word consumed pin or line 225. The data word available pin or line 220 is asserted or de-asserted allowing or not allowing the receiver 20 to accept a data word 107. The data word consumed pin or line 225 informs the sender 10 that the receiver has accepted the data word 107.

When the data word available pin or line 220 is de-asserted, it means that no valid information is currently being placed on the data word line 105, therefore the receiver 20 ignores the data word line 105 and does not try to latch in a new data word 107. This protocol can be modified such that if the data available pin or line 220 is de-asserted and the data word line 105 carries a pre-agreed special token or code word, for example the value 1010..101, the preceding data word 107 was corrupted. The receiver 20 should discard the preceding data word 107 and wait for retransmission. To indicate no valid information being placed on the data word line 105, the sender 10 can de-assert the data available pin or line 220 and force the data word line 105 to carry some value other than the pre-agreed code word.

The special handshaking scheme can also be used in the previously described code spacing scenario.

In the preceding scenarios the fault conditions or disturbances are transient phenomena. It is assumed that the code word is not corrupted. The likelihood of corruption of the code word will depend on electrical noise in the environments. A greater chance of corruption for the code word exists when parity errors are prone to be clustered.

To guard against such conditions, a code word is chosen that remains easily recognizable even when one of the bits is flipped. This works well in the handshaking approach above. If used in the earlier described available code spacing approach, a sparsely used code space is needed. It is, however, a rarity to find a sparsely used code space.

Suppose it is defined that, if the data available pin or line 220 is de-asserted and the data word line 105 carries the value “10101010”, it means the immediately preceding data word 107 was corrupted. To indicate no valid information being placed on the data word line 105, the sender 10 must de-assert the data available pin or line 220 and force the data word line 105 to carry “00000000.” Then the two conditions can be distinguished, even if one of the bits in the data word 107 were flipped.

Referring back to FIG. 3. The RPEDS described involves delivering one data word at a time. The sender 10 computes and remembers the saved parity bit 205; transmits the data word 107; gets back the reverse parity 215; validates the reverse parity 215 against the saved parity 205; and then the sender 10 moves on to the next data word 107 if no error was detected. These added steps from conventional parity error detection schemes translate to some performance drawbacks. To reclaim the lost performance, a solution is to “pipeline” the operations. This can be accomplished with the addition of several parity registers.

To illustrate the idea behind RPEDS, an assumptions is made that the following steps each take one clock cycle of time:

i. sender 10 computes saved parity 205

ii. data word 107 transferred from sender 10 to receiver 20

iii. receiver 20 computes derived parity 210

iv. reverse parity 215 transferred from receiver 20 to sender 10

V. sender 10 compares reverse parity 215 against saved parity 205

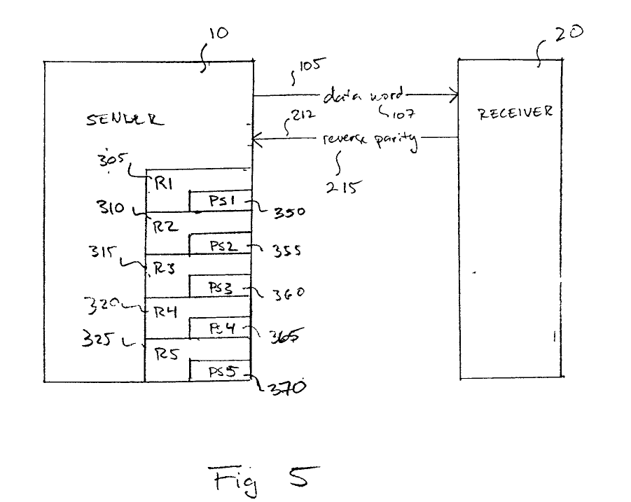

Now referring to FIG. 5, illustrated is a pipeline reverse parity error detection scheme (PRPEDS). Sender 10 has five parity registers R1 305, R2 310, R3 315, R4 320, and R5 325.

The following actions take place at successive clock cycles:

During the first clock cycle, the sender 10 computes saved parity PS1 350 for a first data word D1, saves saved parity PS1 350 in register R1 305.

During the second clock cycle, the sender 10 computes saved parity PS2 for data word D2, and saves saved parity PS2 355 in register R2 310. Data word D1 is transferred to receiver 20.

During the third clock cycle, the sender 10 computes saved parity PS3 360 for data word D3, and saves saved parity PS3 360 in register R3 315. Data word D2 is transferred to receiver 20. Receiver 20 computes the derived parity PD1 for received data word D1.

During the fourth clock cycle, the sender 10 computes saved parity PS4 365 for data word D4, and saves saved parity PS4 365 in register 4 320. Data word D3 is transferred to receiver 20. Receiver 20 computes derived parity PD2 for received data word D2. Derived parity PD1 is sent to sender 10.

During the fifth clock cycle, the sender 10 computes saved parity PS5 for data word D5, and saves saved parity PS5 370 in register R5 325. Data word D4 is transferred to receiver 20. Receiver 20 computes derived parity PD3 for received data word D3. Derived parity PD1 is sent to sender 10. Sender 10 then compares derived parity PD1 with saved parity PS1.

At the end of the fifth cycle, if an error has been detected, the sender 10 alerts the receiver 20 to discard the five immediately preceding data words, and waits for the data words to be retransmitted. If no error is detected, the sender 10 reuses register R1 305 for the next data word, and registers R2 310, R3 315, R4 320, and R4 325 are cleared and used one after another. The system forms a pipeline, boosting performance since the sender does not need to wait to observe the reverse parity of the previous word before it transmits the next word.

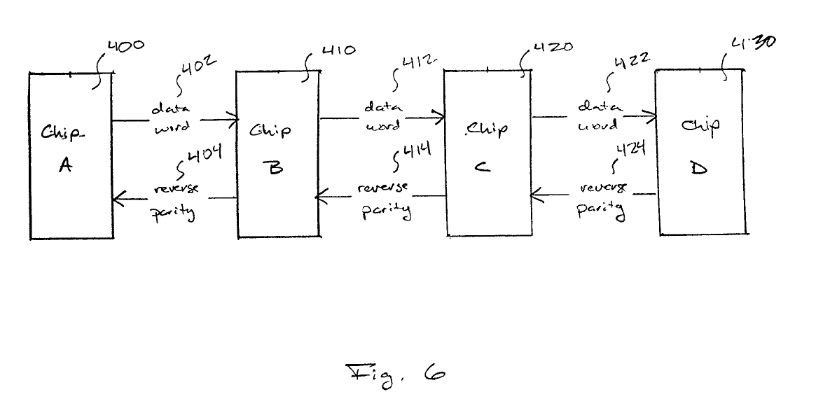

Now referring to FIG. 6, illustrated is a cluster of devices interconnected with one another. Device A 400 forms a virtual circuit to enable it to communicate with device D 425. In one scenario, device D 430 decides to reject the data word 402 from device A 400. The rejection can be due to conditions that include a resource shortage, permission violation, and checksum error.

Instead of adding a separate signal to convey this rejection, the RPEDS is extended. In cascaded reverse parity error detecting scheme (CRPEDS) the reverse parity bit is returned upstream by each device. CRPEDS can be used in a system where a data word is transmitted over several devices, for example in the case of a cluster of network switches. In environments of this type, messages consisting of a stream of data items are conveyed through a dynamically constructed on-demand virtual circuit or a connection that straddles multiple devices.

In CRPEDS the reverse parity is returned upstream by each device, the reverse parity in turn is influenced by the reverse parity it receives downstream. In other words, if device B 410 receives a mismatched reverse parity 414 from device C 420, then device B 410 will also purposely return a flipped reverse parity 404 to device A 400. Device B 410 will compute its derived parity as before, but then flip the derived parity purposely before sending it back to device A 400, only if device 420 returns a wrong reverse parity 414.

Using CRPEDS, device D 425 rejects a message by purposely returning a wrong reverse parity 424. This wrong reverse parity 424 is then transmitted back to device A 400. The logic of the devices can also tear down the virtual circuit as the rejection in the form of a wrong reverse parity makes its way to device A 400.

CRPEDS overloads the meaning of the reverse parity pin, therefore it is suspected that some information must have been lost. If there is in fact a real parity error, for example in device B 410, the error will cause the message to be rejected without device D 430 meaning to do so. This is acceptable, because the parity error would have corrupted the message, and the message should have been rejected.

A more problematic condition is where device D 430 initiates a rejection by flipping its reverse parity line, but that information is eventually lost on the way back to device A 400. This occurs because the reverse parity 424 can get negated again due to a real parity error somewhere in the path, for example at device B 410. In this case, device A 400 will not be informed of the rejection of its message. This can be made harmless by a higher level protocol. The higher level protocol can translate to some performance lost, since an extra amount of time is needed for higher level protocols to become established.

A scenario illustrating this problem is when a device discards the message that it rejected, and device A 400 eventually times out and tries again, or takes other corrective actions. When device D 430 rejects the message due to checksum or other errors, then the parity error at device B 410 can be thought of as a second error for that message. This is actually a double error condition that is not covered by the parity schemes discussed.

Although the present invention has been described in connection with several embodiments, the invention is not intended to be limited to the specific forms set forth herein, but on the contrary, it is intended to cover such alternatives, modifications, and equivalents as can be reasonably included within the spirit and scope of the invention as defined by the appended claims.

What is claimed is:

1. A signaling system comprising:
a sender device that transmits a data word, the sender device determining and saving a saved parity of the data word prior to transmitting the data word;
a receiver device that receives the data word, determines a derived parity of the data word received and sends the derived parity to the sender device;
a first transmission line connecting the sender device and receiver device, and carrying the data word transmitted by the sender device;
a second transmission line connecting the sender device and the receiver device, and carrying the derived parity sent by the receiver device, whereby the sender device receives the derived parity and compares the derived parity against the saved parity.

2. The signaling system of claim 1 further comprising:
an error flag word, whereby the sender device transmits the error flag word to the receiver device when the derived parity does not match the saved parity.

3. The signaling system of claim 2 wherein the error flag is selected from a predetermined word from a set of words in coding space that is transmitted between the sender device and receiver device.

4. The signaling system of claim 1 further comprising:
a data enable line connecting the sender device and the receiver device, whereby sender device disables the data enable line to the receiver device when the derived parity does not match the saved parity.

5. The signaling system of claim 1 wherein the sender device and the receiver device are integrated circuit chips.

6. The signaling system of claim 1 wherein the sender device transmits successive data words,
the receiver device further comprising:
a set of registers, each register storing the derived parity of a transmitted data word,
the sender device further comprising:
a set of registers, each register storing the saved parity of the transmitted data word, and comparing the derived parity of the transmitted data word with the saved parity of the transmitted data word.

7. The signaling system of claim 6 further comprising:
a clock providing successive clock signals whereby the saved parity and the derived parity are calculated for each successive clock signal, the saved parity stored in a register in the sender device and compared to the corresponding derived parity in the receiver device.

8. The signaling system of claim 6 wherein the set of registers in the sender device is at least 2 registers and the set of registers in the receiver device is at least 2 registers.

9. The signaling system of claims 1, 2, 3, 4, 5, 6, 7 or 8 wherein the sender devices retransmits the data word if the saved parity does not match the derived parity.

10. A method of determining single bit error transmission comprising:
calculating a first parity of a data word in a first device;
storing the first parity in the first device;
transmitting the data word by the second device;
receiving the data word by a second device;
calculating a second parity of the data word in the second device;
transmitting the second parity by the second device;
receiving the second parity by the first device; and
comparing the second parity with the first parity in the first device.

11. The method of determining single bit error transmission of claim 10 further comprising:
transmitting an error flag word by the first device to the second device when the first parity does not match the second parity.

12. The method of determining single bit error transmission of claim 11 wherein the error flag is selected from a predetermined word from a set of words in coding space that is transmitted between the sender device and receiver device.

13. The method of determining single bit error transmission of claim 10 further comprising:
disabling a data enable line, the data enable line connecting the first device and the second device, when the derived parity does not match the saved parity.

14. The method of determining single bit error transmission of claim 10 wherein the first device transmits successive data words further comprising:
storing the first parity of a transmitted data word into a register in the first device and
comparing the second parity of the transmitted data word to the first parity stored in the register.

15. The method of determining single bit error transmission of claims 10, 11 12, 13 or 14 wherein the sender devices retransmits the data word if the second parity does not match the first parity.

16. The method of determining single bit error transmission of claim 10 further comprising:
storing the first parity of the data word in a register in the first device;
storing the second parity of the data word in a register in the second device;
transmitting successive data words;
calculating a corresponding first parity for each successive data word;
storing the corresponding first parity bit in a corresponding register in the first device;
calculating a corresponding second parity for each successive data word in the second device;
transmitting the corresponding second parity from second device to the first device;
storing the corresponding second parity in a corresponding register in the first device; and
comparing the corresponding first parity with the corresponding second parity.

17. The method of determining single bit error transmission of claim 16 wherein the number of registers in the first device is at least 2 and the number of registers in the second device is at least 2.

18. A signaling system comprising:
a set of devices interconnected to each other, each device able to
send and receive a data word,
compute a saved parity of the data word,
compute a derived parity of the data word,
send and receive parity from other devices in the set, and
detect error when a wrong parity is received.

19. The signaling system of claim 18 wherein the devices are integrated circuit chips.

20. A method of determining single bit error transmission comprising:
linking a set of devices;
computing and storing a parity by each device;
sending the parity of each device to a connected device;
receiving parity by each device from the connected devices;
determining an error condition by each device; and
relaying the error condition by each device to the connected device.
